(19) United States
(12) Patent Application Publication
(10) Pub. No.: US 2016/0204077 A1
(43) Pub. Date: Jul. 14, 2016

(54) METHOD FOR MANUFACTURING ELECTRONIC DEVICE BY USING FLIP-CHIP BONDING

(71) Applicant: Avago Technologies General IP (Singapore) Pte. Ltd., Singapore (SG)

(72) Inventors: Hyun Mo Ku, Seoul (KR); Jin Jeong, Kyunggi province (KR); Deog Soon Choi, Seoul (KR); Chris Chung, Seoul (KR)

(21) Appl. No.: 14/596,529

(22) Filed: Jan. 14, 2015

(51) Int. Cl. H01L 23/00; H01L 21/56

(52) U.S. Cl. CPC H01L 24/81; H01L 21/565; H01L 2924/014; H01L 2224/8192

(57) ABSTRACT

An electronic device is manufactured by providing a substrate on which a pad including an organic solderability preservative (OSP) film is formed, mounting a die on the substrate such that the die is electrically connected to the pad, performing a molding process on the die mounted on the substrate, and thereafter, forming an oxide film on the substrate by using an oxidation process on the substrate.

### BACKGROUND

In the electronics manufacturing industry, an electronic device such as a semiconductor chipset module is generally fabricated by employing a surface-mount technology (SMT) for incorporating a plurality of electronic components onto a surface of a substrate. Those surface-mounted components may include not only active elements such as a resistor, an inductor and a capacitor, but also passive elements such as a transistor and a die.

Among the above-described surface-mounted components, a the may be mounted onto a substrate by using a bonding technique such as wire bonding and/or hip-chip bonding. When the wire bonding technique is used, the die may be attached to a die pad defined on a surface of the substrate. Then, electrical interconnections may be made between electrodes of the die and corresponding bonding wire pads defined on the surface of the substrate by connecting them with bonding wires.

In contrast, when the flip-chip bonding technique is used, electrical interconnections between the die and the substrate may be made without using bonding wires, First, the die may be flipped over and disposed close to the substrate such that a surface of the die having thereon the electrodes faces the surface of the substrate, and solder bumps deposited on the electrodes are aligned with corresponding flip-chip die pads defined on the surface of the substrate. Then, the solder bumps are reflowed to complete the interconnections therebetween.

In the above-described flip-chip bonding, organic solderability preservative (OSP) films made of an organic compound are deposited on metal films of the flip-chip die pads in order to suppress oxidation of the metal films and enhance adhesiveness of the solder bumps. Especially, the OSP films are known to promote dispersion of the solder bumps being reflowed within an area where the OSP films have been formed and thereby serve to define the boundaries of the interconnections.

Unfortunately, however, in manufacturing electronic devices by using flip-chip bonding, instances of defective products caused by, e.g., contact errors between the die and the substrate have been reported, and damaged OSP films have been blamed as one of the factors creating the contact errors. By way of illustration, as shown in FIG. 12, while the interconnection between the electrode of the die and the flip-chip die pad of the substrate is made in region A in a desirable way, the other interconnections in regions B and C are not In detail, a solder bump is partially connected to the flip-chip die pad in region B, and a solder bump is completely disconnected to the flip-chip die pad in region C.

Accordingly, a series of efforts have been made to figure out what causes the damage to the OSP films and leads to the above-described errors. The investigators have speculated the oxidation process performed on the substrate to be one of the major factors. That is as one of the finishing processes for pads and at pins of the substrate, the oxidation process is performed to provide an oxide film for insulation on a predetermined portion therebetween, as shown in FIG. 13 which is a schematic view of a conventional substrate where the OSP films are formed on a top surface of the substrate and an oxide film CuₓO_{y} is formed on a bottom surface of the substrate.

This oxide film acts as a solder mask and plays a key role in establishing to reliable connection between the substrate and an external device when the electronic device is mounted thereon. For example, the electronic device is mounted onto a test board connected to a measurement means in order to conduct a performance test to detect whether or not the electronic device is defective. The accuracy of the test results may be guaranteed only when the pads and pins of the substrate are properly connected to corresponding conductor areas of the test board.

However, when the oxidation process is being performed, the predetermined position of the substrate on which the oxide film is to be formed as well as the OSP films may be exposed and vulnerable to a process environment, e.g., an etchant that is used to perform the oxidation process. Then, the OSP films, which are made of an organic matter, may be partially or entirely damaged by being subjected to a chemical reaction with the etchant. As a result, contact errors may occur between the die and the substrate, as can he seen from regions B and C of FIG. 12.

In order to avoid the above problem, a finishing process for forming a solder resist on the bottom surface of the substrate by using photoimageable solder resist (PSR) ink may he considered as an alternative to the oxidation process. However, the PSR process has been found less desirable because of its complexity and high cost and extra time required.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased or clarity of discussion. Wherever applicable and practical, like reference numerals refer to like elements.

FIG. 1 is a flowchart illustrating a method for manufacturing an electronic device in accordance with an embodiment of the present invention;

FIGS. 2 and 3 illustrate surfaces of a substrate opposite to each other, which is provided in the method in accordance with the embodiment of the present invention;

FIG. 4 illustrates a vertical section of the substrate that is provided in the method in accordance with the embodiment of the present invention;

FIG. 5 illustrates flip-chip bonding that is performed in the method in accordance with the embodiment of the present invention;

FIG. 6 illustrates a molding process that is performed in the method in accordance with the embodiment of the present invention;

FIG. 7 illustrates an oxidation process that is performed in the method in accordance with the embodiment of the present invention:

FIG. 8 is a flowchart of a method of manufacturing an electronic device in accordance with an embodiment of the present invention;

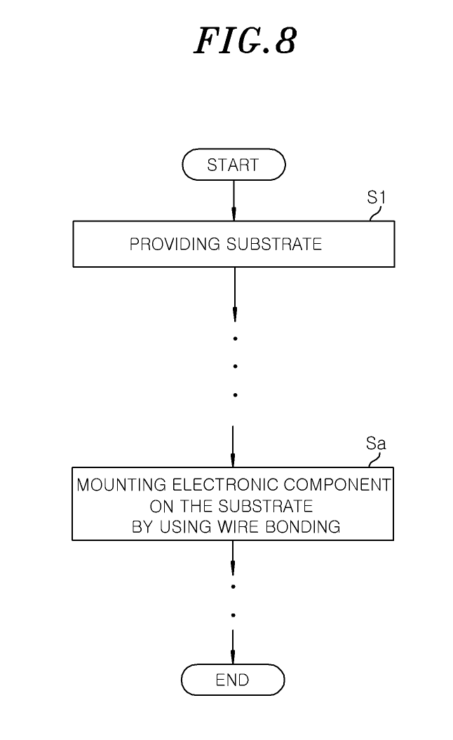

FIG. 9 illustrates wire bonding that is performed in the method in accordance with the embodiment of the present invention;

FIG. 10 is a flowchart of a method of manufacturing an electronic device in accordance with an embodiment of the present invention;

FIG. 11 illustrates part of a test process that is performed in the method in accordance with the embodiment of the present invention;

FIG. 12 schematically illustrates three types of contact states between a die and a substrate in flip-chip bonding; and

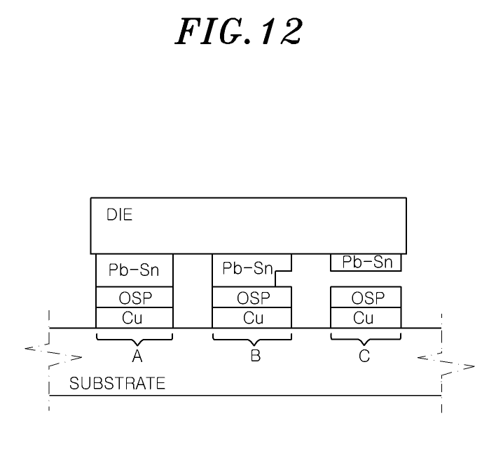

FIG. 13 illustrates a vertical section of a substrate that is provided in a conventional method of manufacturing a semiconductor.

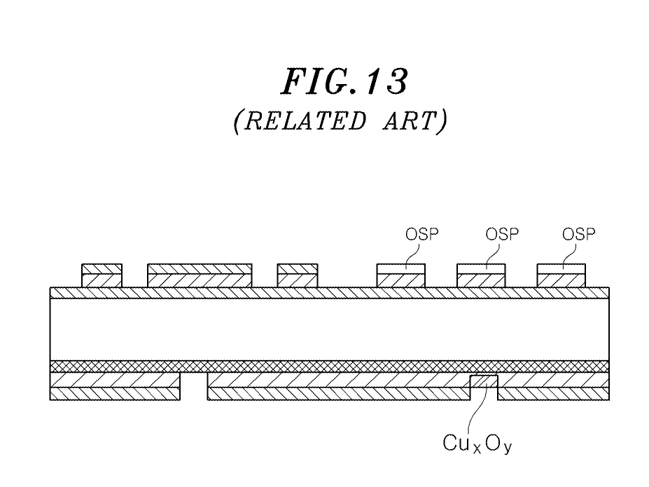

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the an having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the an would consider the cancellation to be acceptable.

As used in the specification and the appended claims and in addition to its ordinary meaning, the term ‘appmximately’ means to within an acceptable limit or amount to one having ordinary skill in the art. For example, ‘approximately the same’ means that one of ordinary skill in the an would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now he “adjacent” to the other element; where “adjacent” means either abutting the other element, or having one or more layers, materials, structures, etc., between the elements.

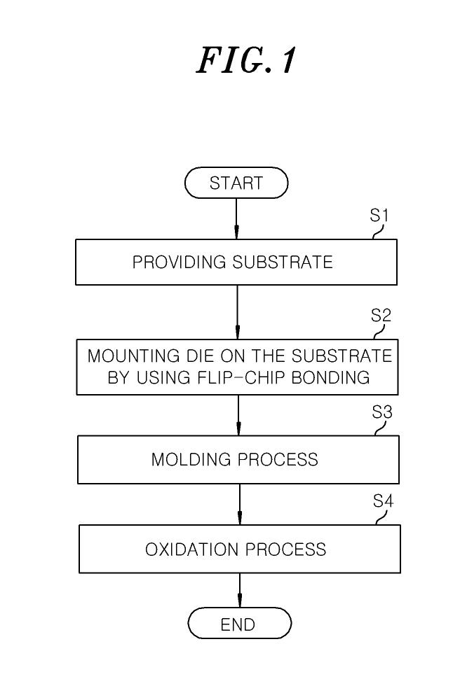

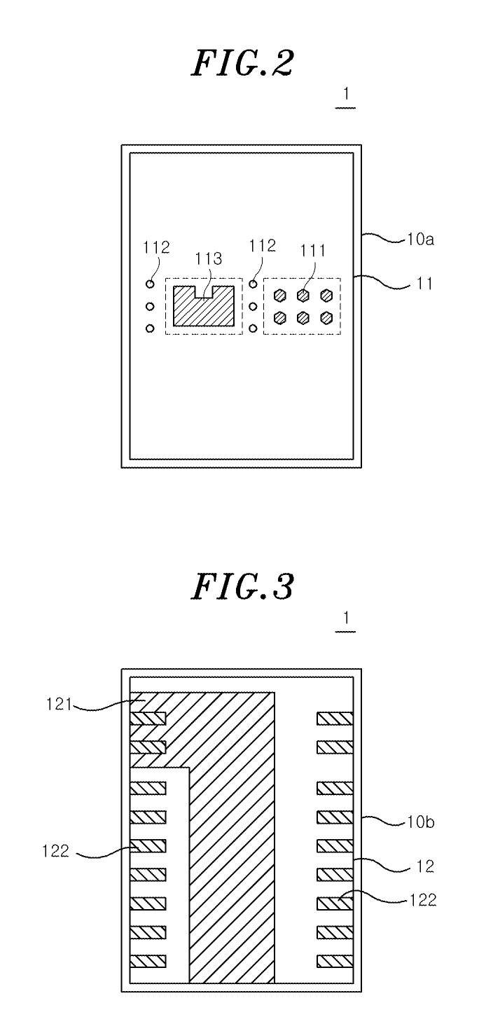

FIG. 1 is a flowchart illustrating a method of manufacturing an electronic device in accordance with an embodiment of the present invention. An electronic device that can be manufactured by the method includes at least a semiconductor chipset module, such as a radio frequency (RF) module, but is not limited to a specific type of device. As can be seen from FIG. 1, the method may include step S1 of providing a substrate as one of components of an electronic device, and step S2 of mounting a die, which is another one of the components of the electronic device, on the substrate by flip-chip bonding. Step S2 is one of steps for assembling the components of the electronic device. The method further includes step S3 of performing a molding process on the substrate on which the die has been mounted, and step S4 of forming an oxide film by performing an oxidation process on the molding-processed substrate. In the method in accordance with the present embodiment, it is noted that the components (that is, the substrate, the die, etc.) of the electronic device are not assembled after each of the components of the electronic device has been completely manufactured. Instead, the components are assembled before said one of the components of the electronic device, i.e., the substrate, is completely manufactured and then the rest if the manufacture of the incomplete component is resumed after the components have been assembled. More specifically, it is noted that step 54 of forming the oxide film is separate from step S1 of providing the substrate and step S2 of mounting the die and is performed after step S3 of performing the molding process. Furthermore, a method in accordance with an embodiment of the present invention may include one or more steps (which will be described later) in addition to steps S1 to S4. Steps S1 to S4 are described in detail below with reference to FIGS. 2 to 7.

First, at step S1, a substrate configured such that electronic components are mounted onto one surface thereof is provided, as a component of an electronic device. This substrate provided at this step corresponds to a substrate in accordance with an embodiment of the present invention. The type of the substrate is not limited to a specific one, but includes at least substrates called a package substrate and a primed circuit board (PCB). Furthermore, the substrate includes not only a substrate for which the manufacture of an electronic, device using only flip-chip bonding is a prerequisite, but also a substrate having a structure with which an electronic device is manufactured using both flip-chip bonding and wire bonding. However, since the structure of the former substrate corresponds to part of the structure of the latter substrate, the following description is given with focus on the structure of the latter substrate in order to avoid the redundancy of description.

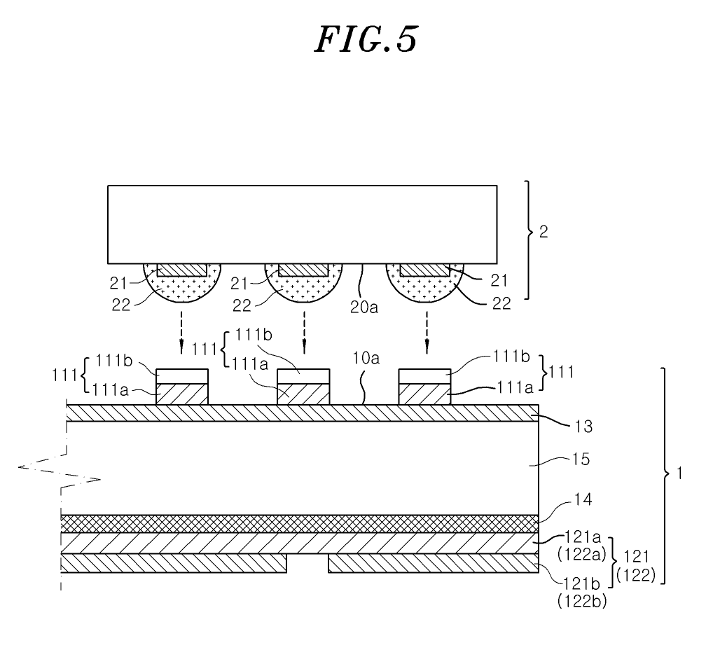

As illustrated, in FIGS. 2 to 4, in a substrate 1 provided for the manufacture of an electronic device, a first conductor area 11 for establishing physical and electrical connection to electronic components and a second conductor area 12 for establishing physical and electrical connection to an external device outside the electronic device are defined. In accordance with an embodiment of the present invention, the first conductor area 11 and the second conductor area 12 may be defined on the opposite surfaces 10a and 10b of the substrate (for example, a top surface and a bottom surface), respectively, and vice versa. Furthermore, as illustrated in FIG. 5, the first and second conductor areas 11 and 12 may be provided in the top and bottom layers 13 and 14 of the substrate 1, and at least one intermediate layer 15, such as an insulating layer or a circuit layer, may be provided between the first and second conductor areas 11 and 12. In addition, the first and second conductor areas 11 and 12 are not necessarily formed on the opposite surfaces of the substrate 1, respectively, but may be formed on the same surface of the substrate 1.

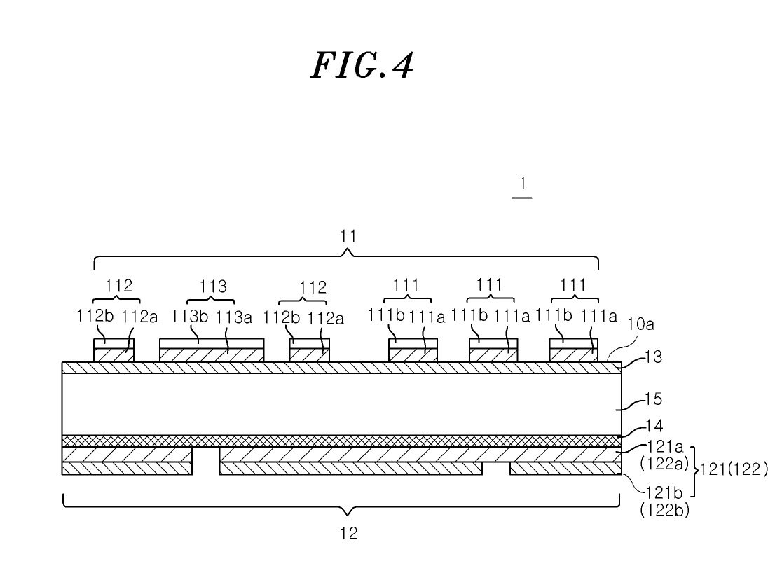

As illustrated in FIGS. 2 and 4, the first conductor area 11 includes flip-chip die pads 111, bonding wire pads 112, and bonding wire die pads 113 that are electrically connected to the electrodes of a die. The pads include one or more (six in FIG. 2) flip-chip die pads 111 that are connected to the die by flip-chip bonding. Each of the flip-chip die pads 111 includes a metal film 111a made of conductive metal, such as copper, and an OSP film 111b conned on the corresponding metal film 111a and made of material including organic matter. The OSP film 111b suppresses the oxidation of the metal film 111a of the flip-chip die pad 111 attributable to heat and also promotes the dispersion of a solder bump within an area in which the OSP film 111b has been formed when the solder bump provided on the die is melted, thereby ultimately functioning to define the boundary of the solder bump that is electrically connected to the flip-chip die pad 111.

Furthermore, the pads of the substrate 1 further include bonding wire pads (also called bonding pads) 112 that are used for connection to bonding wires. Each of the bonding wire pads 112 includes a first metal film 112a made of conductive metal, such as copper. Furthermore, the bonding wire pad 112 may further include a second metal film 112b formed on the first metal film 112a and made of metal, such as gold or nickel. The second metal film 112b becomes a bonding area to which a bonding wire is connected. The second metal film 112b is stacked on the first metal film 112a, and the stacking may be performed by a method known in the relevant technical field, such as electroless gold plating. electrolytic soft gold plating, or the like. Furthermore, the second metal film 112b is not necessarily formed, and may be formed separately from step S1.

Moreover, the pads of the substrate 1 further include a bonding wire die pad 113 that is used to fasten the die to which wire bonding is applied, to the substrate 1. The bonding wire die pad 113 may include a first metal film 113a made of conductive metal, such as copper, and a second metal film 113b formed on the first metal film 113a and made of metal, such as gold or nickel, like the bonding wire pad 112. However, the structure of the bonding wire die pad 113 in accordance with an embodiment of the present invention is not limited to the above-described structure, but may have a structure different from that of the

Meanwhile, as illustrated in FIG. 3, the second conductor area 12 includes at least one pad 121 made of, for example, conductive metal and one or more pins 122 made of conductive metal. The pad 121 and the pins 122 are used to perform connection to, for example, an external device outside the electronic device or a ground, and may each include a first metal film 121a or 122a made of conductive metal, such as copper, a second metal film 122a or 122b made of metal, such as gold or nickel. Furthermore, it should he noted that an oxide film will be formed on part of the first metal film 121a or 122a of the surface 10b of the substrate 1 in order to ensure electrical insulation from solder but the oxide film has not been yet formed on the substrate I provided at the present step S1 in order to prevent the OSP films 111b from being damaged.

Subsequent to step S1, a die also called a semiconductor die, a chip, or a monolithic microwave integrated chipset (MMIC)), that is one of the components of the electronic device, is mounted onto the substrate by flip-chip bonding at step S2. More specifically, as illustrated in FIG. 5, one surface 20a of the die 2 on which electrodes 21 have been formed is located to face the surface 10a of the substrate 1 on which the flip-chip die pads 111 have been formed (for example, to face downward), the electrodes 21 of the die 2 are aligned with the flip-chip die pads 111, and then the die 2 is made to approach the substrate 1. Thereafter, electrical connections to the flip-chip die pads 111 located below solder bumps 22 formed on the electrodes 21 of the die 2 are formed by melting the solder bumps 22. The type of die to which step S2 can be applied is not particularly limited, but includes a die in which, for example, a filter, such as a power amplifier or a duplexer, or a switch has been implemented. Furthermore, although the flip-chip bonding in accordance with the present embodiment may include additional details, descriptions thereof are omitted for ease of description.

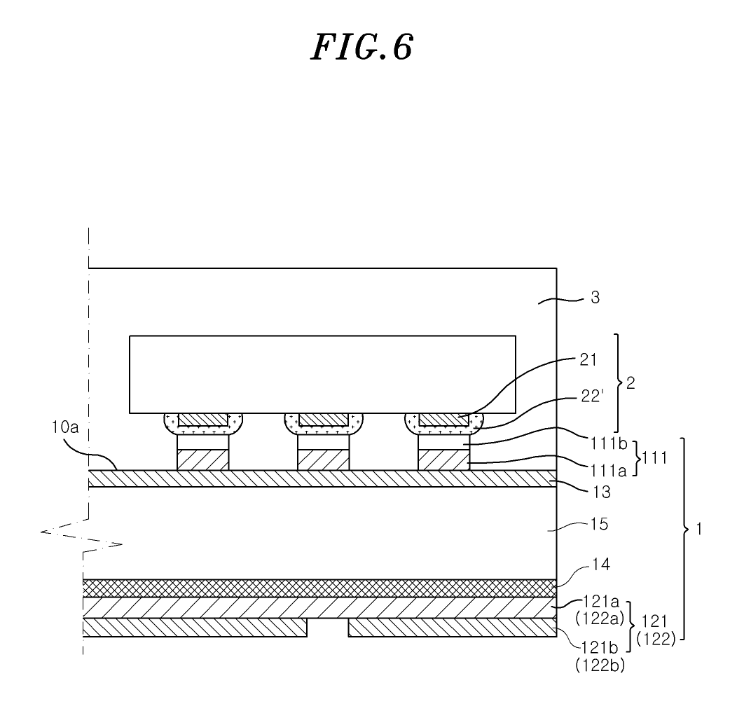

Thereafter, a molding process is performed on the die 2 mounted onto one surface of the substrate 1 at step S3. The molding process in accordance with the present embodiment is performed by supplying molding material 3 around the die 2 brought into contact with the flip-chip die pads 111 via the deformed solder bumps 22,′ applying a predetermined temperature and/or a predetermined pressure to the molding material 3 within a mold and then hardening the molding material 3, thereby allowing the molding material 3 to cover all or parts of one surface 10a of the substrate 1 (for example, the first conductor area 11 or the die 2), at least the OSP films 111b, and thus preventing it or them from being exposed to the outside, as illustrated in FIG. 6. Furthermore, although the molding process in accordance with the present embodiment may include additional details, descriptions thereof are omitted for ease of description.

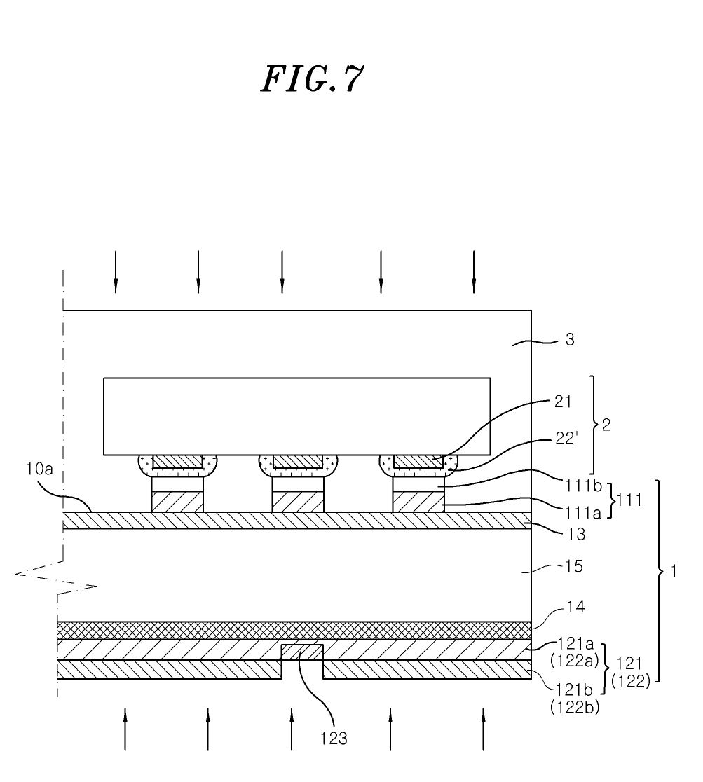

Thereafter, as illustrated in FIG. 7, an oxide film is selectively formed in the second conductor area 12 by performing an oxidation process also called an oxide film printing process) on the substrate 1 at step S4. More specifically, the oxide film is formed by selectively oxidizing a predetermined portion within the second conductor area 12, for example, a portion of the first metal film corresponding to the portion between pads 121, between the pad 121 and the pin 122, and/or between the pins 122. This oxidation process may he performed, for example, by loading the molding-processed substrate 1 into equipment for an oxidation process and then supplying an etchant having the property of oxidizing the first metal film into the equipment, thereby producing a chemical reaction. When the first metal film within the second conductor area 12 is made of copper, the oxide film formed by the oxidation process is a copper-oxide film. Although the overall surface oldie substrate 1 may be exposed to the etchant in order to perform the oxidation process of the present step S4, the OSP films 111b of the first conductor area 11 are protected from the influence of the etchant because they are covered with the molding material 3. Meanwhile, by the oxidation process of the present step S4, unintended electrical connection (for example, a solder bridge) between the pad 121 and the pins 122 within the second conductor area 12 can be prevented, and more reliable and accurate electrical connection can be established when the electronic device completed based on the substrate 1 is mounted onto an external device, such as a test board. Furthermore, although the oxidation process in accordance with the present embodiment may include additional details, descriptions thereof are omitted for ease of description.

The method in accordance with the present embodiment is performed through the above-described steps S1 to S4.

In accordance with the above-described method, in the manufacture of the electronic device including both the OSP films for flip-chip bonding and the oxide film for insulation from unintended electrical connection, although the overall substrate is exposed to the oxidation process that is performed to form the oxide film, the OSP films are covered with molding material that acts as a protection medium, and are thus protected from a chemical reaction with material for the oxidation process. Accordingly, contact errors between the solder dumps provided on the electrodes of the die and the die pads of the substrate, for example, solderability-related errors, attributable to damage to the OSP films can be reduced. Furthermore, this case can reduced time and costs, compared to the case of replacing an oxide film with PSR ink.

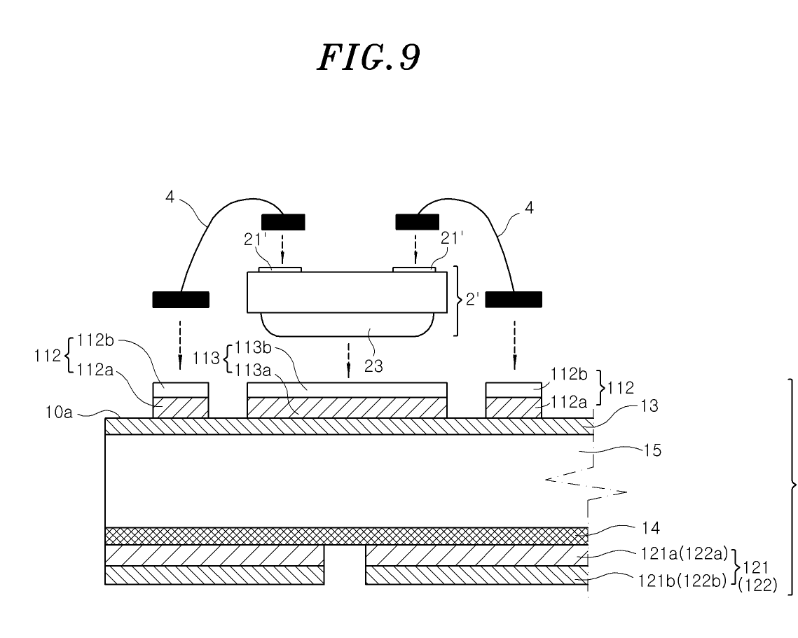

Meanwhile, a method in accordance with an embodiment of the present invention may include another step in addition to steps S1 to S4. More specifically, the method in accordance with the present embodiment may include the step of assembling components including the substrate 1 for example, step Sa of mounting another electronic component on the substrate 1, as illustrated in FIG. 9, in addition to the die mounted by the flip-chip bonding at step S2. Step Sa may be performed before, simultaneously with, or after step S2. If the additional electronic component that is mounted at step Sa has been designed to be covered with the molding material at step S3, step Sa is performed before step S3. In contrast, if the additional electronic component that is mounted at step Sa has been designed to be subjected to an oxidation process a step S4, step Sa is performed before step S4. The additional electronic component that is processed at step Sa is not limited to a particular type of component, and may be mounted by flip-chip bonding or wire bonding. Since the case where the additional electronic component is mounted by flip-chip bonding is the same as the above-described case, only the case where the additional electronic component is mounted by wire bonding is described below. As illustrated in FIG. 9, the additional electronic component 2′ is fastened to the bonding wire die pad 113, with the surface of the additional electronic component 2′ on which the electrodes 21′ have been formed facing a direction identical to the direction that the surface 10a of the substrate 1 faces, for example, example, facing upward, and with the opposite surface of the additional electronic component 2′ on which the solder bump 23 has been formed facing the surface 10a of the substrate 1, that is, facing downward. Furthermore, bonding wires 4 (sometimes referred to as lead wires) are connected between the electrodes 21′ of the additional electronic component 2′ and the bonding wire pads 112. The bonding wires 4 may be made of aluminum, copper, silver, gold, or other materials. A wire bonding process may be performed by ball bonding, wedge bonding or stitch bonding that is well known in the relevant technical field, but is not particularly limited thereto.

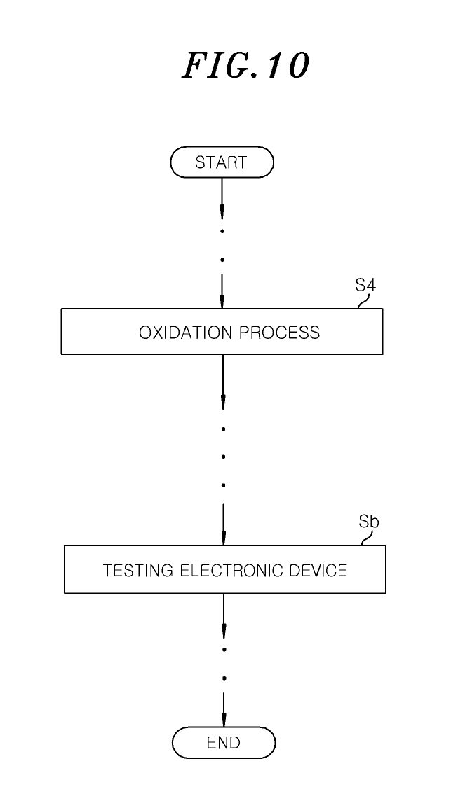

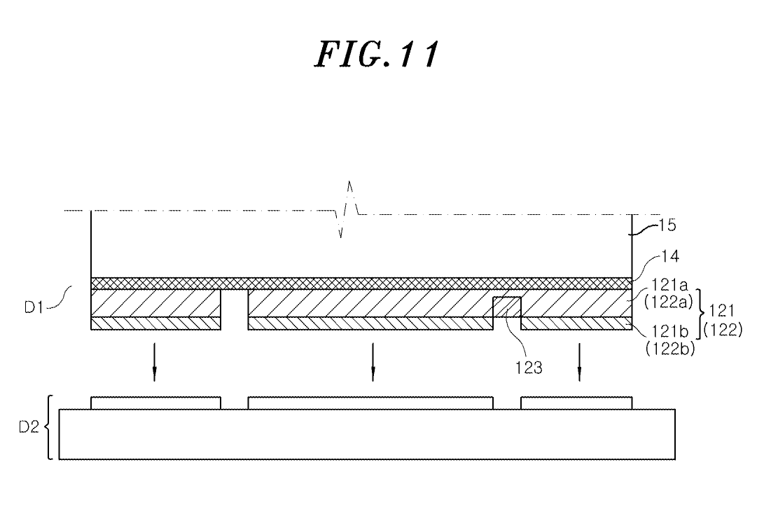

Meanwhile, a method in accordance with an embodiment of the present invention may include an additional step, for example, step Sb of mounting a complete electronic device D1 on a test board D2 and then conducting a test, as illustrated in FIG. 10, in addition to step S1 to S4 and Sa. It is preferred that step Sb is performed after step S4. The oxide film formed at step S4 allows the electronic device D1 to be more accurately and electrically connected to the test board D2 at step Sb, as illustrated in FIG. 11.

Furthermore, one or more processes, such as the inspection of the substrate onto which the electronic component has been mounted, laser marking, and/or singulation, may be performed after step S2.

In addition, the method in accordance with the present embodiment may be performed by a plurality of agents. By way of example, step S1 may he performed by a substrate manufacturer, steps S2 to S4 and Sa may be performed by a package assembly manufacturer, and step Sb may he performed by another electronic device manufacturer. In this case, the step of transferring the intermediate product or finished product of the electronic device from one agent to another agent may be added to each of the steps.

Although the specific embodiments of the present invention have been disclosed for illustrative purposes, those skilled in the art will appreciate that various modifications, additions and substitutions are possible without departing from the scope and spirit of the invention as disclosed in the accompanying claims.

While the invention has been shown and described with respect to the preferred embodiments, it will be understood by those skilled in the art that various changes and modifications may be made without departing from the spirit and scope of the invention as defined in the following claims.

What is claimed is:

1. A method for manufacturing an electronic device, comprising:
providing a substrate on which a pad including an organic solderability preservative (OSP) film is formed;
mounting a die on the substrate such that the die is electrically connected to the pad;
performing a molding process on the die mounted on the substrate; and, thereafter, forming an oxide film on the substrate by using an oxidation process on the substrate.

2. The method of claim 1, wherein said performing of the molding process includes covering the OSP film with a molding compound, and
wherein said forming of the oxide film includes exposing at least part of the molding compound that covers the OSP film to a gaseous material for forming the oxide film.

3. The method of claim 1, wherein said forming of the oxide film is selectively performed on part of a conductor area formed on the substitute.

4. The method of claim 1, wherein the oxide film includes copper oxide.

5. The method of claim 3, wherein the oxide film includes copper oxide.

6. The method of claim 1, wherein said mounting the die is performed by using flip-chip bonding.

7. The method of claim 1, wherein the die includes an electrode and a solder bump formed on the electrode, and
wherein said mounting of the die includes:
disposing the die such that the electrode faces the pad;
aligning the electrode with the pad; and
reflowing the solder bump and thereby bringing the solder bump into contact with the OSP film of the pad.

8. The method of claim 1, wherein in said providing of the substrate, an additional pad is formed on the substrate, and
wherein the method further comprises:
mounting an electronic component on the substrate by using wire bonding such that the electronic component is electrically connected to the additional pad of the substrate.

9. A method for manufacturing an electronic device, comprising:
providing a substrate which includes a first conductor region and a second conductor region, the first conductor region including an organic solderability preservative (OSP) film;
covering the OSP film with a molding compound; and thereafter,
partially oxidizing the second conductor region to form an insulation layer.

10. The method of claim 9, wherein said oxidizing is performed while exposing at least part of the molding compound that covers the OSP film to a gaseous material for oxidizing the second conductor region.

11. The method of claim 9, wherein the oxide film includes copper oxide.

12. The method of claim 10, wherein the oxide film includes copper oxide.

13. The method of claim 9, further comprising:
mounting, prior to said covering, a die on the substrate by using flip-chip bonding such that an electrical interconnection is formed between the die and the first conductor region via the OSP film.

14. The method of claim 13, wherein the substrate further includes a third conductor region, and
wherein the method further comprises:
mounting an electronic component on the substrate by using wire bonding such that a bonding wire connects the electronic component and the third conductor region.

15. A method for manufacturing an electronic device, comprising:
partially covering a substrate with a molding compound,
wherein the substrate includes an organic solderability preservative (OSP) film and a metal film which are laterally spaced apart, the OSP film being electrically connected to an electronic component which is mounted on the substrate, the metal film including a region which is to be oxidized, and
wherein said covering is performed while leaving the region uncovered.

16. The method of claim 15, further comprising:
oxidizing the region to form an insulation layer while exposing at least part of the molding compound that covers the OSP film to a gaseous material for said oxidizing.

17. The method of claim 15, wherein the oxide film includes copper oxide.

18. The method of claim 16, wherein the oxide film includes copper oxide.

19. The method of claim 15, wherein the OSP film is electrically connected to the electronic component by flip-chip bonding.

20. The method of claim 15, wherein the substrate further includes an additional metal film, and
wherein the method further comprises:
mounting an additional electronic component on the substrate by using wire bonding such that a bonding wire connects the additional electronic component and the additional metal film.
